(19) United States
(12) Patent Application Publication
(10) Pub. No.: US 2026/0052762 A1
(43) Pub. Date: Feb. 19, 2026

(54) SEMICONDUCTOR DEVICE

(71) Applicant: Samsung Electronics Co., Ltd., Suwon-si (KR)

(72) Inventors: Seong-Yul PARK, Suwon-si (KR); Yong-Ah KIM, Suwon-si (KR); Hyungjoo YOUN, Suwon-si (KR)

(73) Assignee: Samsung Electronics Co., Ltd., Suwon-si (KR)

(21) Appl. No.: 19/013,581

(22) Filed: Jan. 8, 2025

(30) Foreign Application Priority Data
Aug. 14, 2024 (KR) 10-2024-0109407

(51) Int. Cl. H10D 84/83; H10D 30/00; H10D 30/01; H10D 62/10; H10D 62/13; H10D 84/01

(52) U.S. Cl. CPC H10D 84/832; H10D 30/502; H10D 30/503; H10D 30/506; H10D 62/121; H10D 62/151; H10D 30/0194; H10D 84/013; H10D 84/0149; H10D 84/0151

(57) ABSTRACT

A semiconductor device may include a first fin pattern, a first source/drain pattern on the first fin pattern, a second fin pattern spaced apart in a first direction from the first fin pattern, a second source/drain pattern on the second fin pattern, a first gate electrode overlapping the first fin pattern and extending in a second direction crossing the first direction, a second gate electrode overlapping the second fin pattern and extending in the second direction, and a first dummy structure between the first fin pattern and the second fin pattern and between the first gate electrode and the second gate electrode. The first dummy structure may include first to third line parts extending in the second direction, first and second connection parts connecting the first and second line parts to each other, and a third connection part connecting the second and third line parts to each other.

### CROSS-REFERENCE TO RELATED APPLICATION

This U.S. nonprovisional application claims priority under 35 U.S.C § 119 to Korean Patent Application No. 10-2024-0109407 filed on Aug. 14, 2024 in the Korean Intellectual Property Office, the disclosure of which is hereby incorporated by reference in its entirety.

### BACKGROUND

Inventive concepts relate to a semiconductor device, and more particularly, to a semiconductor device including a dummy structure.

A semiconductor device may include an integrated circuit having metal oxide semiconductor field effect transistors (MOSFETs). As a size and a design rule of the semiconductor device may be gradually decreased, sizes of the MOSFETs also increasingly may be scaled down. The scale down of MOSFETs may deteriorate operating characteristics of the semiconductor device. Accordingly, various research has been developed to manufacture semiconductor devices having excellent performances while overcoming limitations due to integration of the semiconductor device.

### SUMMARY

Some embodiments of inventive concepts provide a semiconductor device with increased reliability and/or improved electrical properties and/or a method of fabricating the same.

According to some embodiments of inventive concepts, a semiconductor device may include a first fin pattern; a first source/drain pattern on the first fin pattern; a second fin pattern spaced apart in a first direction from the first fin pattern; a second source/drain pattern on the second fin pattern; a first gate electrode overlapping the first fin pattern and extending in a second direction, the second direction crossing the first direction; a second gate electrode overlapping the second fin pattern and extending in the second direction; and a first dummy structure between the first fin pattern and the second fin pattern and between the first gate electrode and the second gate electrode. The first dummy structure may include a first line part extending in the second direction, a second line part extending in the second direction, a third line part extending in the second direction, a first connection part and a second connection part connecting the first line part and the second line part to each other, and a third connection part connecting the second line part and third line part to each other. The first connection part, the second connection part, and the third connection part may be spaced apart from each other in the second direction. A distance in the second direction between the first connection part and the second connection part may be greater than a distance in the second direction between the first connection part and the third connection part. The distance in the second direction between the first connection part and the second connection part may be greater than a distance in the second direction between the second connection part and the third connection part.

According to some embodiments of inventive concepts, a semiconductor device may include a first fin pattern; a first source/drain pattern on the first fin pattern; a second fin pattern spaced apart in a first direction from the first fin pattern; a second source/drain pattern on the second fin pattern; a first gate electrode overlapping the first fin pattern and extending in a second direction, the second direction crossing the first direction; a second gate electrode overlapping the second fin pattern and extending in the second direction; and a first dummy structure between the first fin pattern and the second fin pattern and between the first gate electrode and the second gate electrode. The first dummy structure may include a first line part extending in the second direction, a second line part extending in the second direction, a third line part extending in the second direction, a first connection part and a second connection part connecting the first line part and the second line part to each other, and a third connection part connecting the second line part and the third line part to each other. The first connection part, the second connection part, and the third connection part may be spaced apart from each other in the second direction. The third connection part may be between the first connection part and the second connection part.

According to some embodiments of inventive concepts, a semiconductor device may include a first fin pattern; a first source/drain pattern on the first fin pattern; a second fin pattern spaced apart in a first direction from the first fin pattern; a second source/drain pattern on the second fin pattern; a first gate electrode overlapping the first fin pattern and extending in a second direction, the second direction crossing the first direction; a second gate electrode overlapping the second fin pattern and extending in the second direction; a dummy structure between the first fin pattern and the second fin pattern; and a plurality of inner dummy spacers surrounded by the dummy structure. The dummy structure may include a first line part extending in the second direction, a second line part extending in the second direction, a third line part extending in the second direction, a first connection part, a second connection part, a third connection part, a fourth connection part, and a fifth connection part. The first connection part, the second connection part, and the third connection part may connect the first line part and the second line part to each other. The fourth connection part and the fifth connection part may connect the second line part and the third line part to each other. The fourth connection part may be between the first connection part and the second connection part. The fifth connection part may be between the second connection part and the third connection part. The inner dummy spacers may include a first inner dummy spacer, a second inner dummy spacer, and a third inner dummy spacer. The first inner dummy spacer may be surrounded by the first line part, the second line part, the first connection part, and the second connection part. The second inner dummy spacer may be surrounded by the first line part, the second line part, the second connection part, and the third connection part. The third inner dummy spacer may be surrounded by the second line part, the third line part, the fourth connection part, and the fifth connection part.

### BRIEF DESCRIPTION OF DRAWINGS

FIG. 1A illustrates a plan view showing a semiconductor device according to some embodiments.

FIG. 1B illustrates an enlarged view showing section Q1 of FIG. 1A.

FIG. 1C illustrates a cross-sectional view taken along line A-A′ of FIG. 1B.

FIG. 1D illustrates a cross-sectional view taken along line B-B′ of FIG. 1B.

FIG. 1E illustrates a cross-sectional view taken along line C-C′ of FIG. 1B.

FIG. 1F illustrates a cross-sectional view taken along line D-D′ of FIG. 1B.

FIG. 1G illustrates a cross-sectional view taken along line E-E′ of FIG. 1B.

FIG. 1H illustrates an enlarged view showing section Q2 of FIG. 1B.

FIG. 1I illustrates an enlarged view showing section Q3 of FIG. 1B.

FIGS. 2A, 2B, 3A, 3B, 4A, 4B, 4C, 5A, 5B, 5C, 6A, 6B, 7A, 7B, and 7C illustrate cross-sectional views showing a method of fabricating a semiconductor device according to some embodiments.

FIG. 8A illustrates a plan view showing a semiconductor device according to some embodiments.

FIG. 8B illustrates an enlarged view showing section Q4 of FIG. 8A.

FIG. 9 illustrates a cross-sectional view showing a semiconductor device according to some embodiments.

### DETAILED DESCRIPTION OF EMBODIMENTS

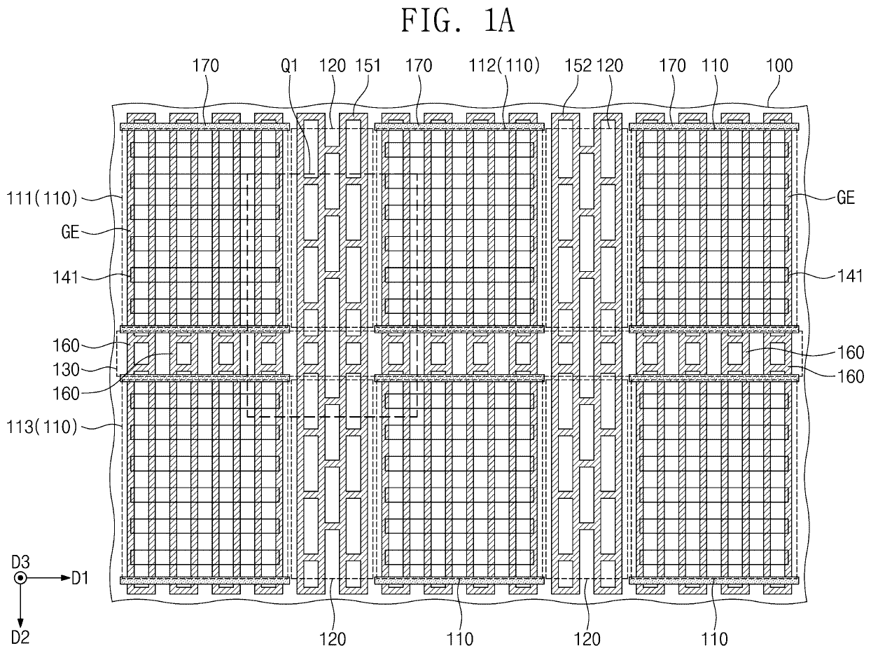

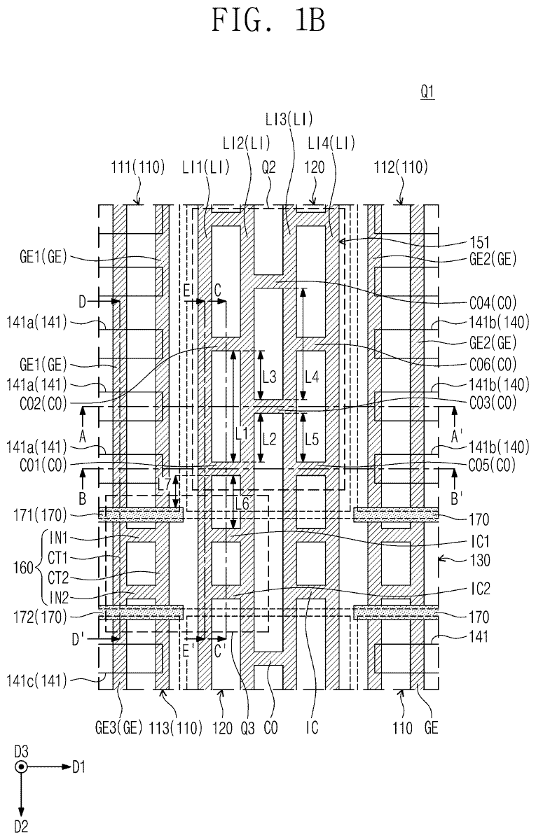

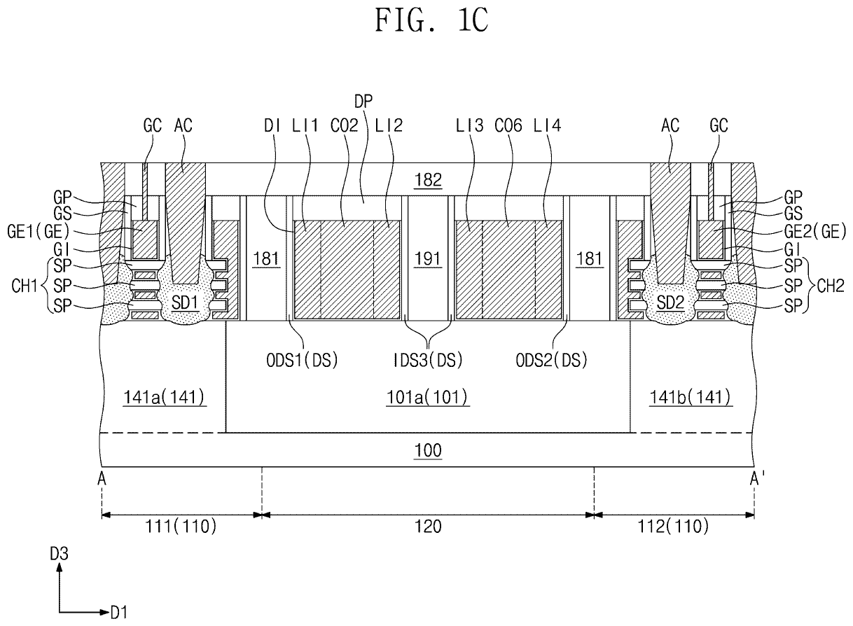

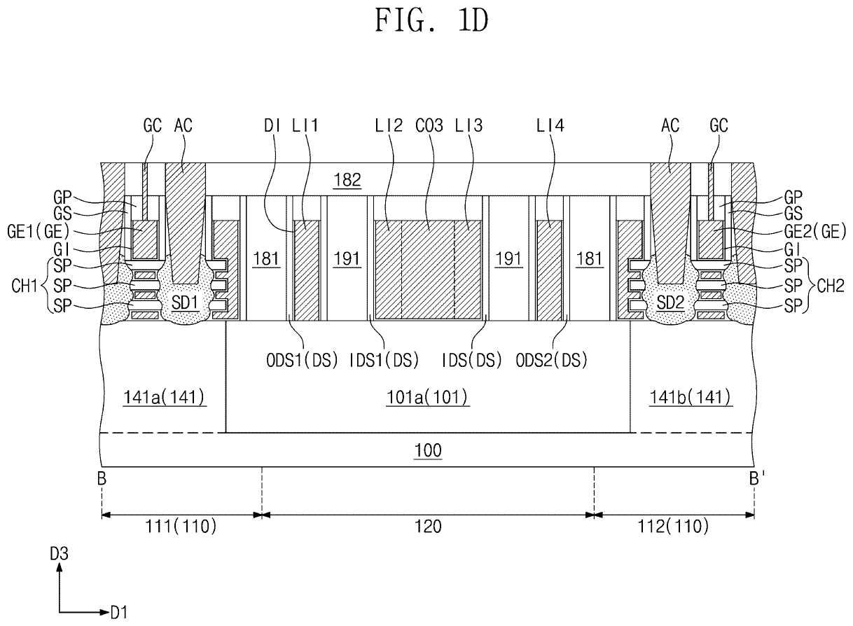

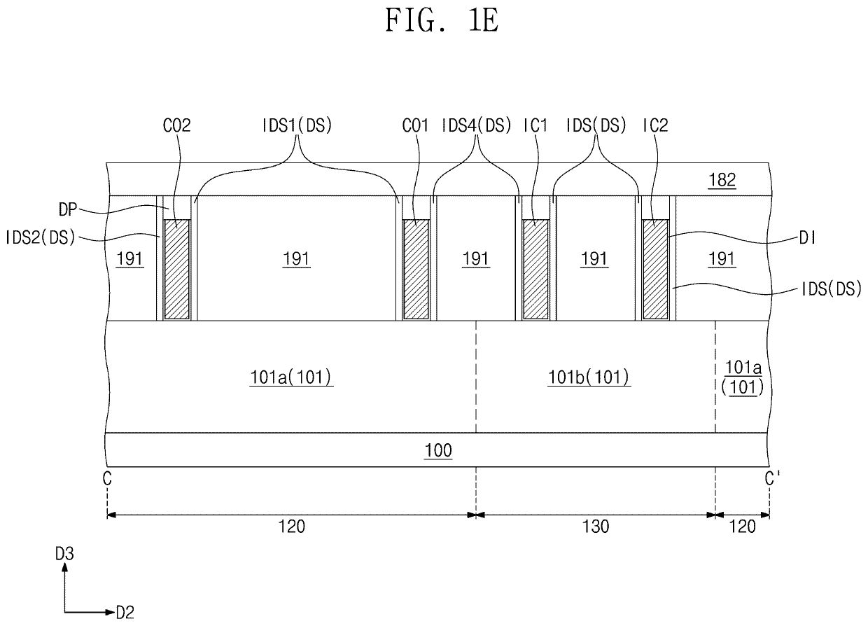

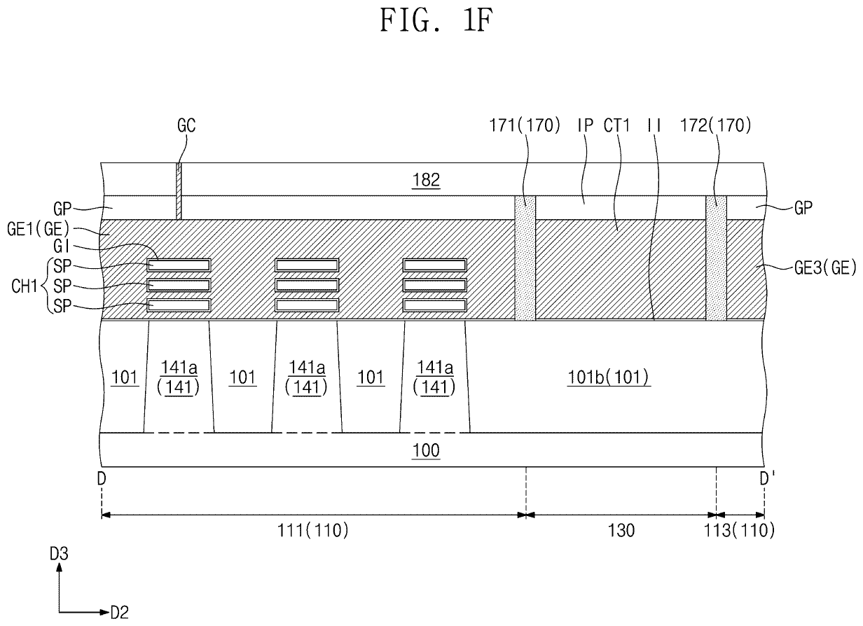

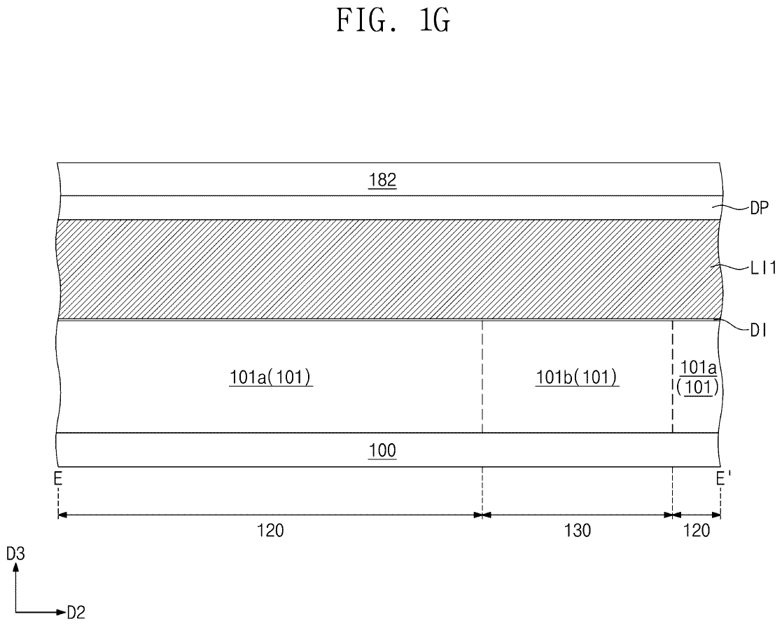

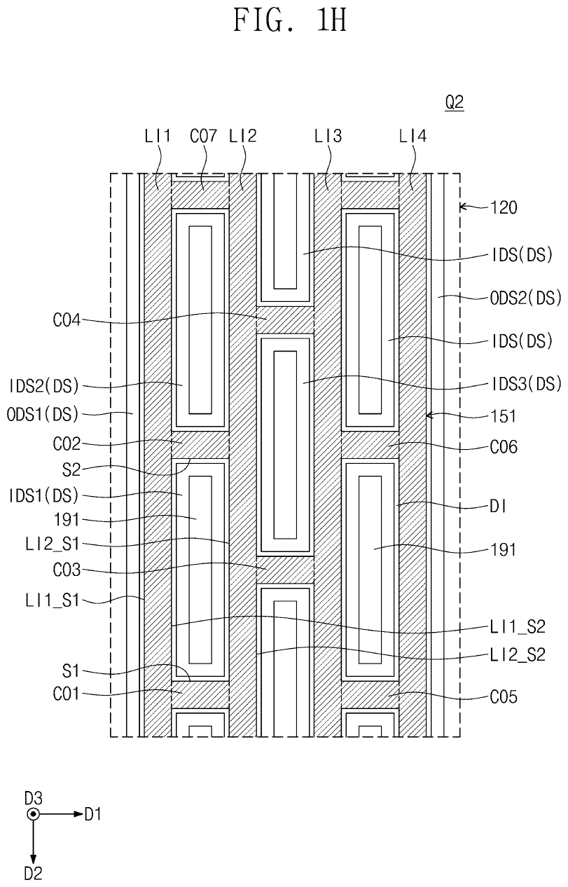

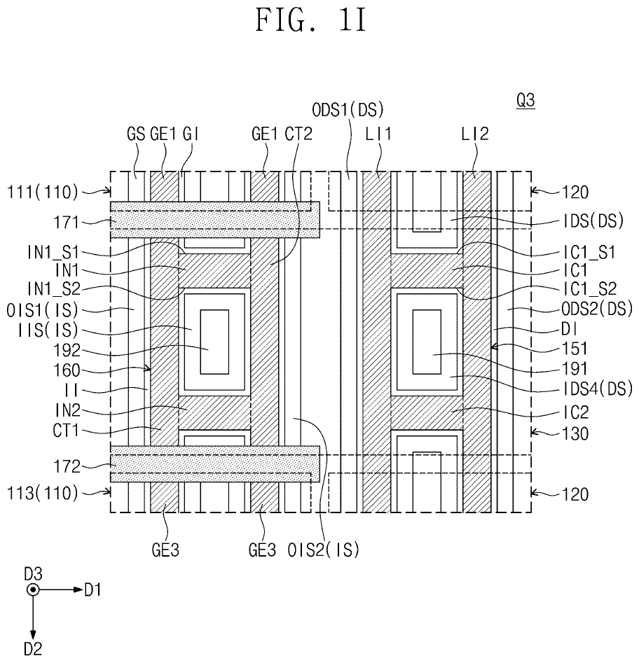

FIG. 1A illustrates a plan view showing a semiconductor device according to some embodiments. FIG. 1B illustrates an enlarged view showing section Q1 of FIG. 1A. FIG. 1C illustrates a cross-sectional view taken along line A-A′ of FIG. 1B. FIG. 1D illustrates a cross-sectional view taken along line B-B′ of FIG. 1B. FIG. 1E illustrates a cross-sectional view taken along line C-C′ of FIG. 1B. FIG. 1F illustrates a cross-sectional view taken along line D-D′ of FIG. 1B. FIG. 1G illustrates a cross-sectional view taken along line E-E′ of FIG. 1B. FIG. 1H illustrates an enlarged view showing section Q2 of FIG. 1B. FIG. 1I illustrates an enlarged view showing section Q3 of FIG. 1B.

Referring to FIG. 1A, a semiconductor device may include a substrate 100. The substrate 100 may be a semiconductor substrate, a dielectric substrate, or a semiconductor-on-insulator (SOI) substrate. The semiconductor substrate may include, for example, silicon (Si), germanium (Ge), silicon-germanium (SiGe), gallium phosphate (GaP), or gallium arsenide (GaAs).

The substrate 100 may have a plate shape that extends along a plane elongated in a first direction D1 and a second direction D2. The first direction D1 and the second direction D2 may intersect each other. For example, the first direction D1 and the second direction D2 may be horizontal directions that are orthogonal to each other.

The substrate 100 may include block regions 110, first interface regions 120, and a second interface region 130. The block regions 110 may include logic cells. In this description, the logic cell may refer to a logic device (e.g., AND, OR, XOR, XNOR, and inverter) that performs a specific function. The logic cell may include transistors included in the logic circuit.

The first interface region 120 may be disposed between the block regions 110 that are adjacent to each other in the first direction D1. The block regions 110 may include a first block region 111 and a second block region 112 that are adjacent to each other in the first direction D1, and the first interface region 120 may be disposed between the first and second block regions 111 and 112. The first interface region 120 may extend in the second direction D2.

The second interface region 130 may be disposed between the block regions 110 that are adjacent to each other in the second direction D2. The block regions 110 may include a first block region 111 and a third block region 113 that are adjacent to each other in the second direction D2, and the second interface region 130 may be disposed between the first and third block regions 111 and 113. The second interface region 130 may be disposed between the first interface regions 120 that are adjacent to each other in the second direction D2. The second interface region 130 may extend in the first direction D1.

The block region 110 may include fin patterns 141 and gate electrodes GE that overlap each other in a third direction D3. The third direction D3 may intersect the first direction D1 and the second direction D2. For example, the third direction D3 may be a vertical direction perpendicular to the first direction D1 and the second direction D2.

A first dummy structure 151 and a second dummy structure 152 may be provided. The first dummy structure 151 and the second dummy structure 152 may overlap in the third direction D3 with the first interface region 120 and the second interface region 130, respectively. Each of the first and second dummy structures 151 and 152 may be disposed between the block regions 110 that are adjacent to each other in the first direction D1. The first dummy structure 151 may be provided between the first and second block regions 111 and 112.

Interface patterns 160 may be provided. The interface pattern 160 may overlap in the third direction D3 with the second interface region 130. The interface pattern 160 may be disposed between the block regions 110 that are adjacent to each other in the second direction D2. Portions of the interface pattern 160 may be provided between the first and third block regions 111 and 113. The gate electrode GE, the first and second dummy structures 151 and 152, and the interface pattern 160 may include the same conductive material. The first and second dummy structures 151 and 152 and the interface pattern 160 may be electrically floated.

Gate separation layers 170 may be provided and may extend in the first direction D1. The gate separation layer 170 may be disposed on a boundary between the block region 110 and the second interface region 130. In some embodiments, the gate separation layers 170 may further include a gate separation layer 170 disposed on the block region 110.

Referring to FIGS. 1B, 1C, 1D, 1E, 1F, and 1G, the substrate 100 may include the fin patterns 141. The fin patterns 141 may extend in the first direction D1. The fin patterns 141 may be portions of the substrate 100 that protrude in the third direction D3. The fin patterns 141 may include a semiconductor material.

In some embodiments, a lower portion of the substrate 100 may be absent, and the fin patterns 141 may be separated from each other. In some embodiments, the fin patterns 141 separated from each other without the lower portion of the substrate 100 may include a dielectric material.

The fin patterns 141 may include first fin patterns 141a disposed on the first block region 111, second fin patterns 141b disposed on the second block region 112, and third fin patterns 141c disposed on the third block region 113.

The first pattern 141a and the second fin pattern 141b may be spaced apart from each other in the first direction D1. The first fin pattern 141a and the second fin pattern 141b may be adjacent to each other in the first direction D1. The first fin pattern 141a and the second fin pattern 141b may be disposed on an imaginary straight line that extends in the first direction D1. The first fin pattern 141a and the third fin pattern 141c may be spaced apart from each other in the second direction D2. The first fin pattern 141a and the third fin pattern 141c may be disposed on an imaginary straight line that extends in the second direction D2.

A distance in the second direction D2 between the first fin patterns 141a that are adjacent to each other in the second direction D2 may be less than a distance in the second direction D2 between the first and third fin patterns 141a and 141c that are adjacent to each other in the second direction D2. A pitch in the second direction D2 between the first fin patterns 141a may be less than a pitch in the second direction D2 between the first and third fin patterns 141a and 141c that are adjacent to each other in the second direction D2.

A device isolation layer 101 may be provided on the substrate 100. The device isolation layer 101 may surround the fin patterns 141. The device isolation layer 101 may include a dielectric material. For example, the device isolation layer 101 may include oxide.

The device isolation layer 101 may include a first isolation part 101a disposed on the first interface region 120 and a second isolation part 101b disposed on the second interface region 130. The first isolation part 101a may be disposed between the first and second block regions 111 and 112. The first isolation part 101a may be disposed between the first and second fin patterns 141a and 141b. The second isolation part 101b may be disposed between the first and third block regions 111 and 113. The second isolation part 101b may be disposed between the first and third fin patterns 141a and 141c.

The fin patterns 141 may be provided thereon with source/drain patterns SD1 and SD2. The first fin pattern 141a may be provided thereon with first source/drain patterns SD1. The second fin pattern 141b may be provided thereon with second source/drain patterns SD2. The third fin pattern 141c may be provided thereon with third source/drain patterns.

The source/drain patterns SD1 and SD2 may be epitaxial patterns formed by a selective epitaxial growth (SEG) process. The source/drain patterns SD1 and SD2 may include a semiconductor material. For example, the source/drain patterns SD1 and SD2 may include at least one selected from silicon (Si), silicon-germanium (SiGe), and germanium (Ge). An impurity may be doped into the source/drain patterns SD1 and SD2.

Channel structures CH1 and CH2 may be provided. The channel structures CH1 and CH2 may overlap in the third direction D3 with the fin pattern 141. First channel structures CH1 may be provided which overlap in the third direction D3 with the first fin pattern 141a. Second channel structures CH2 may be provided which overlap in the third direction D3 with the second fin pattern 141b. Third channel structures may be provided which overlap in the third direction D3 with the third fin pattern 141c.

Each of the channel structures CH1 and CH2 may include semiconductor patterns SP that overlap each other in the third direction D3. In some embodiments, the semiconductor patterns SP may include silicon (Si). For example, the semiconductor pattern SP may include crystalline silicon. In some embodiments, the semiconductor pattern SP may include silicon-germanium (SiGe).

The gate electrodes GE may be provided. The gate electrodes GE may extend in the second direction D2. The gate electrode GE may overlap in the third direction D3 with the fin pattern 141. First gate electrodes GE1 may be provided which overlap in the third direction D3 with the first fin pattern 141a. Second gate electrodes GE2 may be provided which overlap in the third direction D3 with the second fin pattern 141b. Third gate electrodes GE3 may be provided which overlap in the third direction D3 with the third fin pattern 141c.

The gate electrodes GE may overlap in the third direction D3 with the channel structures CH1 and CH2. The gate electrode GE may include portions provided between the semiconductor patterns SP. The gate electrode GE and the semiconductor patterns SP of the channel structure CH1 or CH2 may constitute and/or form parts of a three-dimensional field effect transistor (e.g., MBCFET or GAAFET). The gate electrode GE may include a conductive material.

Gate dielectric layers GI may be provided. The gate dielectric layer GI may be in contact with the gate electrode GE, the semiconductor pattern SP, and the source/drain pattern SD1 or SD2. The gate dielectric layer GI may separate the gate electrode GE from the semiconductor pattern SP and the source/drain pattern SD1 or SD2. The gate dielectric layer GI may include a dielectric material. For example, the gate dielectric layer GI may include oxide.

Gate spacers GS may be provided. A pair of gate spacers GS may be disposed on opposite sides of the gate electrode GE. The gate spacers GS may extend in the second direction D2. The gate spacers GS may have their top surfaces coplanar with that of a first interlayer dielectric layer 181 which will be discussed below. The gate spacers GS may include a dielectric material.

Gate capping patterns GP may be provided. The gate capping pattern GP may be provided on the gate electrode GE. The gate capping pattern GP may extend in the second direction D2. The gate capping pattern GP may include a dielectric material.

Each of the first and second dummy structures 151 and 152 may include line parts LI and connection parts CO. The line parts LI may extend in the second direction D2. The line parts LI may be spaced apart from each other in the first direction D1. The connection parts CO may extend in the first direction D1. The connection part CO may connect the line parts LI to each other. A length in the second direction D2 of the line part LI may be greater than a length in the first direction D1 of the connection part CO.

The line parts LI and the connection parts CO may overlap in the third direction D3 with the first interface region 120. The line parts LI and the connection parts CO may overlap in the third direction D3 with the first isolation part 101a of the device isolation layer 101. The line parts LI may overlap in the third direction D3 with the second interface region 130. The line parts LI may overlap in the third direction D3 with the second isolation part 101b of the device isolation layer 101.

The number of the line parts LI and the number of the connection parts CO included in one dummy structure 151 or 152 are not limited to that shown.

The first dummy structure 151 may be disposed between the first and second fin patterns 141a and 141b. The first dummy structure 151 may include a first line part LI1, a second line part LI2 adjacent in the first direction D1 to the first line part LI1, a third line part LI3 adjacent in the first direction D1 to the second line part LI2, and a fourth line part LI4 adjacent in the first direction D1 to the third line part LI3. The second and third line parts LI2 and LI3 may be disposed between the first and fourth line parts LI1 and LI4.

The first dummy structure 151 may include a first connection part CO1 that connects the first and second line parts LI1 and LI2 to each other, a third connection part CO3 and a fourth connection part CO4 that connect the second and third line parts LI2 and LI3 to each other, and a fifth connection part CO5 and a sixth connection part CO6 that connect the third and fourth line parts LI3 and LI4 to each other. The first, second, third, fourth, fifth, and sixth connection parts CO1, CO2, CO3, CO4, CO5, and CO6 may be disposed between the first and second block regions 111 and 112. The first, second, third, fourth, fifth, and sixth connection parts CO1, CO2, CO3, CO4, CO5, and CO6 may overlap in the third direction D3 with the first interface region 120 between the first and second block regions 111 and 112. The first, second, third, and fourth connection parts CO1, CO2, CO3, and CO4 may be spaced apart from each other in the second direction D2.

A distance L1 in the second direction D2 between the first and second connection parts CO1 and CO2 may be greater than a distance L2 in the second direction D2 between the first and third connection parts CO1 and CO3. The third connection part CO3 may be disposed between the first and second connection parts CO1 and CO2. A distance L2 in the second direction D2 between the first and third connection parts CO1 and CO3 may be the same as a distance L3 in the second direction D2 between the second and third connection parts CO2 and CO3. The distance L1 in the second direction D2 between the first and second connection parts CO1 and CO2 may be greater than the distance L3 in the second direction D2 between the second and third connection parts CO2 and CO3.

The distance L1 in the second direction D2 between the first and second connection parts CO1 and CO2 may be the same as a distance LA in the second direction D2 between the third and fourth connection parts CO3 and CO4. The second connection part CO2 may be disposed between the third and fourth connection parts CO3 and CO4.

The fifth connection part CO5 and the first connection part CO1 may be disposed on an imaginary straight line that extends in the first direction D1. The sixth connection part CO6 and the second connection part CO2 may be disposed on an imaginary straight line that extends in the first direction D1. The third connection part CO3 may be disposed between the fifth and sixth connection parts CO5 and CO6. The sixth connection part CO6 may be disposed between the third and fourth connection parts CO3 and CO4.

A distance L5 in the second direction D2 between the third and fifth connection parts CO3 and CO5 may be the same as the distance L2 in the second direction D2 between the first and third connection parts CO1 and CO3.

The gate separation layers 170 may include a first gate separation layer 171 and a second gate separation layer 172 that are disposed between the first and third block regions 111 and 113. The first gate separation layer 171 may be disposed between the first block region 111 and the second interface region 130. The second gate separation layer 172 may be disposed between the third block region 113 and the second interface region 130. The second interface region 130 may be disposed between the first and second gate separation layers 171 and 172.

The first gate separation layer 171 may be in contact with the first gate electrode GE1 and the interface pattern 160. The second gate separation layer 172 may be in contact with the third gate electrode GE3 and the interface pattern 160. The first gate separation layer 171 may be disposed between the first gate electrode GEL and the interface pattern 160. The second gate separation layer 172 may be disposed between the third gate electrode GE3 and the interface pattern 160. The first and second gate separation layers 171 and 172 may be disposed between the first and third gate electrodes GE1 and GE3. The first and second gate separation layers 171 and 172 may be adjacent to each other in the second direction D2.

A distance L7 in the second direction D2 between the first connection part CO1 and the first gate separation layer 171 may be the same as a distance in the second direction D2 between the fifth connection part CO5 and the first gate separation layer 171. A distance in the second direction D2 between the second connection part CO2 and the first gate separation layer 171 may be the same as a distance in the second direction D2 between the sixth connection part CO6 and the first gate separation layer 171.

A distance in the second direction D2 between the third connection part CO3 and the first gate separation layer 171 may be greater than a distance in the second direction D2 between the first connection part CO1 and the first gate separation layer 171. The distance in the second direction D2 between the third connection part CO3 and the first gate separation layer 171 may be less than the distance in the second direction D2 between the second connection part CO2 and the first gate separation layer 171.

A distance in the second direction D2 between the fourth connection part CO4 and the first gate separation layer 171 may be greater than the distance in the second direction D2 between the first connection part CO1 and the first gate separation layer 171. The distance in the second direction D2 between the fourth connection part CO4 and the first gate separation layer 171 may be greater than the distance in the second direction D2 between the second connection part CO2 and the first gate separation layer 171.

A distance in the second direction D2 between the third connection part CO3 and the second interface region 130 may be greater than a distance in the second direction D2 between the first connection part CO1 and the second interface region 130. The distance in the second direction D2 between the third connection part CO3 and the second interface region 130 may be greater than a distance in the second direction D2 between the second connection part CO2 and the second interface region 130.

Each of the first and second dummy structures 151 and 152 may further include interface connection parts IC. The interface connection parts IC may connect the line parts LI to each other. The interface connection parts IC may extend in the first direction D1. A length in the second direction D2 of the line part LI may be greater than a length in the first direction D1 of the interface connection part IC. The length in the first direction D1 of the interface connection part IC may be the same as a length in the first direction D1 of the connection part CO.

The interface connection parts IC may overlap in the third direction D3 with the second interface region 130. The interface connection parts IC may overlap in the third direction D3 with the second isolation part 101b of the device isolation layer 101. The interface connection parts IC may be disposed between the first interface regions 120 that are spaced apart from each other in the second direction D2.

The number of the interface connection parts IC included in one dummy structure 151 or 152 is not limited to that shown.

The first dummy structure 151 may include a first interface connection part IC1 and a second interface part IC2 between the first and second line parts LI1 and LI2. The first interface connection part IC1 and the second interface connection part IC2 may be disposed between the first gate separation layer 171 and the second gate separation layer 172. The first interface connection part IC1 and the second interface connection part IC2 may be disposed between the first block region 111 and the third block region 113. A distance in the second direction D2 between the first interface connection part IC1 and the first gate separation layer 171 may be less than a distance in the second direction D2 between the second interface connection part IC2 and the first gate separation layer 171.

A distance L6 in the second direction D2 between the first interface connection part IC1 and the first connection part CO1 may be the same as the distance L2 in the second direction D2 between the first connection part CO1 and the third connection part CO3. The distance L6 in the second direction D2 between the first interface connection part IC1 and the first connection part CO1 may be less than the distance LI in the second direction D2 between the first connection part CO1 and the second connection part CO2.

In some embodiments, the distance L6 in the second direction D2 between the first interface connection part IC1 and the first connection part CO1 may be greater than the distance L2 in the second direction D2 between the first connection part CO1 and the third connection part CO3.

Each of the interface patterns 160 may include a first contact part CT1, a second contact part CT2, a first intervening part IN1, and a second intervening part IN2. The first and second contact parts CT1 and CT2 may extend in the second direction D2. The first and second contact parts CT1 and CT2 may be spaced apart from each other in the first direction D1. The first and second intervening parts IN1 and IN2 may extend in the first direction D1. The first and second intervening parts IN1 and IN2 may connect the first and second contact parts CT1 and CT2 to each other.

The first and second contact parts CT1 and CT2 of the interface pattern 160 between the first and third fin patterns 141a and 141c may be in contact with the first gate separation layer 171 and the second gate separation layer 172. The first and second intervening parts IN1 and IN2 of the interface pattern 160 between the first and third fin patterns 141a and 141c may be spaced apart in the second direction D2 from the first gate separation layer 171 and the second gate separation layer 172.

A distance in the second direction D2 between the first gate separation layer 171 and the first intervening part IN1 of the interface pattern 160 between the first and third fin patterns 141a and 141c may be less than a distance in the second direction D2 between the first gate separation layer 171 and the second intervening part IN2 of the interface pattern 160 between the first and third fin patterns 141a and 141c.

The first interface connection part IC1 and the first intervening part IN1 of the interface pattern 160 between the first and third fin patterns 141a and 141c may be positioned on an imaginary straight line that extends in the first direction D1. The second interface connection part IC2 and the second intervening part IN2 of the interface pattern 160 between the first and third fin patterns 141a and 141c may be positioned on an imaginary straight line that extends in the first direction D1.

A distance in the second direction D2 between the first intervening part IN1 and the second intervening part IN2 of the interface pattern 160 between the first and third fin patterns 141a and 141c may be the same as a distance in the second direction D2 between the first and second interface connection parts IC1 and IC2.

Dummy dielectric layers D1 may be provided. The dummy dielectric layers D1 may be in contact with the first and second dummy structures 151 and 152. The dummy dielectric layer D1 may include a dielectric material. For example, the dummy dielectric layer D1 may include oxide.

Dummy spacers DS may be provided. The dummy spacer DS may be in contact with the dummy dielectric layer D1. The dummy spacer DS may include a dielectric material.

Dummy capping patterns DP may be provided. The dummy capping patterns DP may be provided on the first and second dummy structures 151 and 152. The dummy capping pattern DP may include a dielectric material.

Interface dielectric layers II may be provided. The interface dielectric layer II may be in contact with the interface pattern 160. The interface dielectric layer II may include a dielectric material. For example, the interface dielectric layer II may include oxide.

Interface spacers (see IS of FIG. 1I) may be provided. The interface spacer IS may be in contact with the interface dielectric layer II. The interface spacer IS may include a dielectric material.

Interface capping patterns IP may be provided. The interface capping pattern IP may be provided on the interface pattern 160. The interface capping pattern IP may include a dielectric material.

A first interlayer dielectric layer 181 may be provided. The first interlayer dielectric layer 181 may be provided on the first and second source/drain patterns SD1 and SD2 and the gate spacers GS. A second interlayer dielectric layer 182 may be provided on the first interlayer dielectric layer 181. The first and second interlayer dielectric layers 181 and 182 may include a dielectric material. For example, the first and second interlayer dielectric layers 181 and 182 may include oxide.

Active contacts AC may be provided to penetrate the first and second interlayer dielectric layers 181 and 182. The active contacts AC may be electrically connected to the first and second source/drain patterns SD1 and SD2. The active contact AC may include a conductive material.

Gate contacts GC may be provided. At least one of the gate electrodes GE may be electrically connected to the gate contact GC. The gate contact GC may penetrate the second interlayer dielectric layer 182 and the gate capping pattern GP. The gate contact GC may include a conductive material.

Referring to FIGS. 1C, 1D, 1E, 1F, 1G, and 1H, the dummy spacers DS may include a first outer dummy spacer ODS1, a second outer dummy spacer ODS2, and inner dummy spacers IDS adjacent to the first dummy structure 151. The first and second outer dummy spacers ODS1 and ODS2 may extend in the second direction D2. The first and second outer dummy spacers ODS1 and ODS2 may be spaced apart in the first direction D1 from each other across the first dummy structure 151. The first dummy structure 151 may be provided between the first and second outer dummy spacers ODS1 and ODS2. The inner dummy spacers IDS may be surrounded by the first dummy structure 151.

The first dummy structure 151 may include a seventh connection part CO7 that connects the first and second line parts LI1 and LI2 to each other.

The inner dummy spacers IDS may include a first inner dummy spacer IDS1 surrounded by the first and second line parts LI1 and LI2 and the first and second connection parts CO1 and CO2, a second inner dummy spacer IDS2 surrounded by the second and seventh connection parts CO2 and CO7, and a third inner dummy spacer IDS3 surrounded by the third and fourth connection parts CO3 and CO4.

The third inner dummy spacer IDS3 and the first inner dummy spacer IDS1 may be disposed on an imaginary straight line that extends in the first direction D1. The third inner dummy spacer IDS3 and the second inner dummy spacer IDS2 may be disposed on an imaginary straight line that extends in the first direction D1. The first, second, and third inner dummy spacers IDS1, IDS2, and IDS3 may have the same length in the second direction D2. The first, second, and third inner dummy spacers IDS1, IDS2, and IDS3 may have the same length in the first direction D1.

A distance in the second direction D2 between the first inner dummy spacer IDS1 and the first gate separation layer 171 may be less than a distance in the second direction D2 between the third inner dummy spacer IDS3 and the first gate separation layer 171. The distance in the second direction D2 between the third inner dummy spacer IDS3 and the first gate separation layer 171 may be less than a distance in the second direction D2 between the second inner dummy spacer IDS2 and the first gate separation layer 171. The third inner dummy spacer IDS3 may be disposed between the first and second inner dummy spacers IDS1 and IDS2.

The third connection part CO3 and the first inner dummy spacer IDS1 may be disposed on an imaginary straight line that extends in the first direction D1. The fourth connection part CO4 and the second inner dummy spacer IDS2 may be disposed on an imaginary straight line that extends in the first direction D1. The second connection part CO2 and the third inner dummy spacer IDS3 may be disposed on an imaginary straight line that extends in the first direction D1.

The first line part LI1 may have a first sidewall LI1_S1 and a second sidewall LI1_S2 opposite to the first sidewall LI1_S1. The first, second, and seventh connection parts CO1, CO2, and CO7 may be connected to the second sidewall LI2_S1 of the first line part LI1.

The second line part LI2 may have a first sidewall LI2_S1 and a second sidewall LI2_S2 opposite to the first sidewall LI2_S1. The first sidewall LI2_S1 of the second line part LI2 may face the second sidewall LI2_S1 of the first line part LI1. The first, second, and seventh connection parts CO1, CO2, and CO7 may be connected to the first sidewall LI2_S1 of the second line part LI2. The third and fourth connection parts CO3 and CO4 may be connected to the second sidewall LI2_S2 of the second line part LI2.

A sidewall S1 of the first connection part CO1 and a sidewall S2 of the second connection part CO2 may be connected to the first sidewall LI2_SI1 of the second line part LI2 and the second sidewall LI2_S1 of the first line part LI1. The first inner dummy spacer IDS1 may be surrounded by the first sidewall LI2_S1 of the second line part LI2, the second sidewall LI2_S2 of the first line part LI1, the sidewall S1 of the first connection part CO1, and the sidewall S2 of the second connection part CO2.

First inner dielectric layers 191 may be provided. The first inner dielectric layer 191 may be surrounded by the inner dummy spacer IDS. The first inner dielectric layer 191 may be surrounded by the dummy structure 151 or 152. The first inner dielectric layer 191 may include a dielectric material.

Referring to FIGS. 1C, 1D, 1E, 1F, 1G, and 1I, the interface spacers IS may include a first outer interface spacer OIS1, a second outer interface spacer OIS2, and an inner interface spacer IIS adjacent to the interface pattern 160 between the first and second gate separation layers 171 and 172. The first and second outer interface spacers OIS1 and OIS2 may extend in the second direction D2. The first and second outer interface spacers OIS1 and OIS2 may be spaced apart from each other in the first direction D1. The interface pattern 160 may be provided between the first and second outer interface spacers OIS1 and OIS2. The inner interface spacer IIS may be surrounded by the interface pattern 160. The inner interface spacer IIS may be surrounded by the first and second contact parts CT1 and CT2 and the first and second intervening parts IN1 and IN2.

The inner dummy spacers IDS may include a fourth inner dummy spacer IDS4 surrounded by the first and second line parts LI1 and LI2 and the first and second interface connection parts IC1 and IC2. The fourth inner dummy spacer IDS4 may be disposed between the first and second outer dummy spacers ODS1 and ODS2.

The inner interface spacer IIS and the fourth inner dummy spacer IDS4 may have the same length in the first direction D1. The inner interface spacer IIS and the fourth inner dummy spacer IDS4 may have the same length in the second direction D2. A distance in the second direction D2 between the inner interface spacer IIS and the first gate separation layer 171 may be the same as a distance in the second direction D2 between the fourth inner dummy spacer IDS4 and the first gate separation layer 171. The inner interface spacer IIS and the fourth inner dummy spacer IDS4 may be disposed on an imaginary straight line that extends in the first direction D1.

The first intervening part IN1 may have a first sidewall IN1_S1 and a second sidewall IN1_S2 opposite to the first sidewall IN1_S1. The first interface connection part IC1 may have a first sidewall IC1_S1 and a second sidewall IC1_S2 opposite to the first sidewall IC1_S1.

The first sidewall IN1_S1 of the first intervening part IN1 and the first sidewall IC1_S1 of the first interface connection part IC1 may be disposed on an imaginary straight line that extends in the first direction D1. The second sidewall IN1_S2 of the first intervening part IN1 and the second sidewall IC1_S2 of the first interface connection part IC1 may be disposed on an imaginary straight line that extends in the first direction D1. The first and second sidewalls IN1_S1 and IN1_S2 of the first intervening part IN1 and the first and second sidewalls IC1_S1 and IC1_S2 of the first interface connection part IC1 may be parallel to the first direction D1.

Second inner dielectric layers 192 may be provided. The second inner dielectric layer 192 may be surrounded by the inner interface spacer IIS. The second inner dielectric layer 192 may be surrounded by the interface pattern 160.

The first contact part CT1, the first gate electrode GE1, and the third gate electrode GE3 may have their sidewalls disposed on an imaginary straight line that extends in the second direction D2. The second contact part CT2, the first gate electrode GE1, and the third gate electrode GE3 may have their sidewalls disposed on an imaginary straight line that extends in the second direction D2.

The semiconductor device according to some embodiments may have a structure in which the dummy structure 151 or 152 disposed between the block regions 110 has the line parts LI whose structure is similar to that of the gate electrode GE, and thus a separate pattern for separation of the block regions 110 may not be needed to be disposed between the block regions 110. Accordingly, the semiconductor device may become compact-sized.

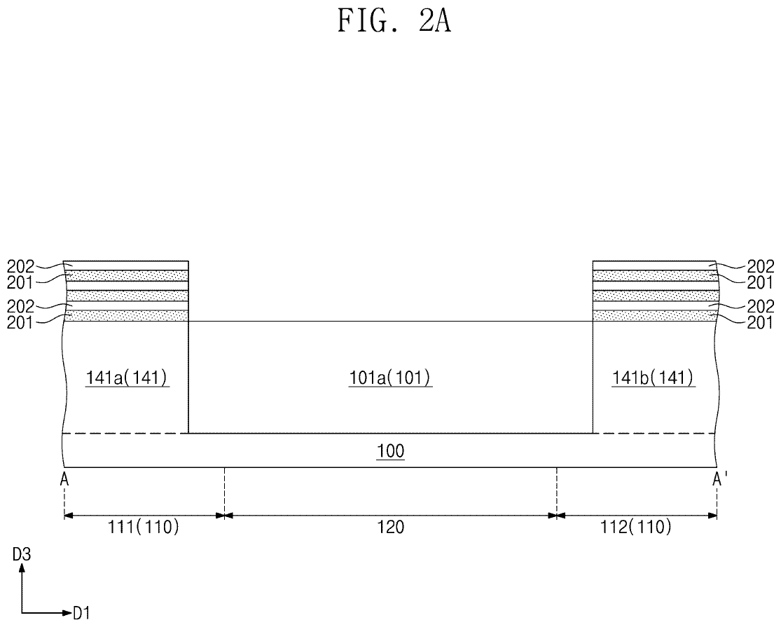

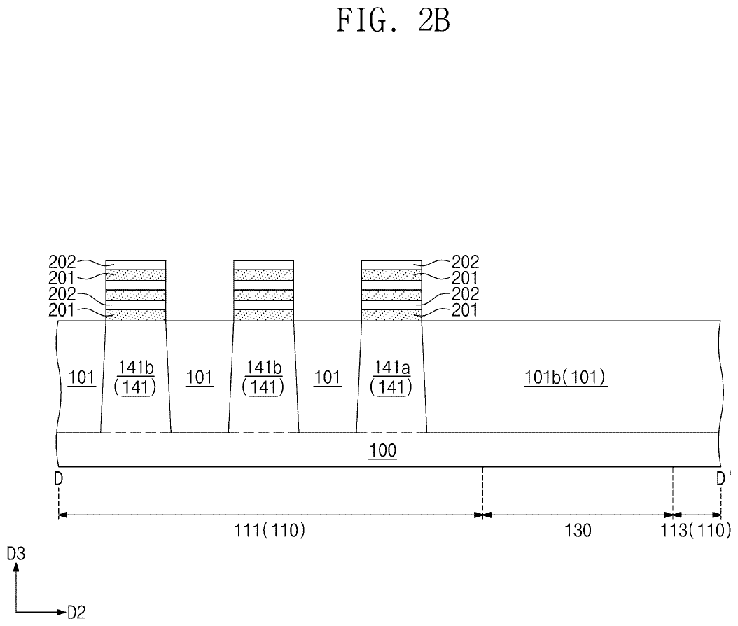

FIGS. 2A, 2B, 3A, 3B, 4A, 4B, 4C, 5A, 5B, 5C, 6A, 6B, 7A, 7B, and 7C illustrate cross-sectional views showing a method of fabricating a semiconductor device according to some embodiments.

Referring to FIGS. 2A and 2B, fin patterns 141, sacrificial layers 201, and semiconductor layers 202 may be formed. The formation of the fin patterns 141, the sacrificial layers 201, and the semiconductor layers 202 may include alternately forming preliminary sacrificial layers and preliminary semiconductor layers on a substrate 100, and patterning the preliminary sacrificial layers, the preliminary semiconductor layers, and the substrate 100.

The preliminary sacrificial layers may be patterned to form the sacrificial layers 201. The preliminary semiconductor layers may be patterned to form the semiconductor layers 202. The substrate 100 may be patterned to form the fin patterns 141.

The sacrificial layer 201 may include a material having an etch selectivity with respect to the semiconductor layer 202. For example, the sacrificial layer 201 may include silicon-germanium, and the semiconductor layer 202 may include silicon. A device isolation layer 101 may be formed.

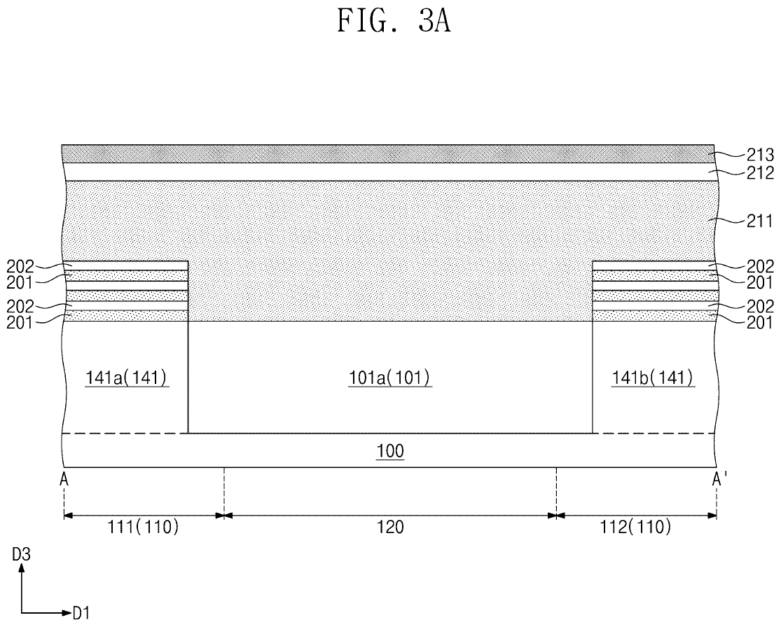

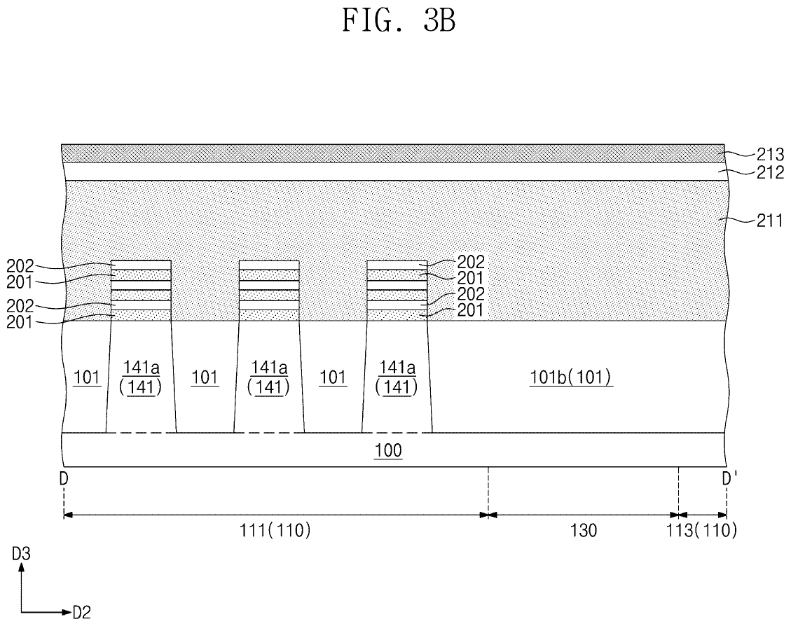

Referring to FIGS. 3A and 3B, a preliminary pattern layer 211 may be formed. The preliminary pattern layer 211 may cover the sacrificial layers 201, the semiconductor layers 202, and the device isolation layer 101. The preliminary pattern layer 211 may include, for example, polysilicon.

A mask layer 212 may be formed on the preliminary pattern layer 211. The mask layer 212 may include a dielectric material.

A photoresist layer 213 may be formed on the mask layer 212. The photoresist layer 213 may include a photoresist material.

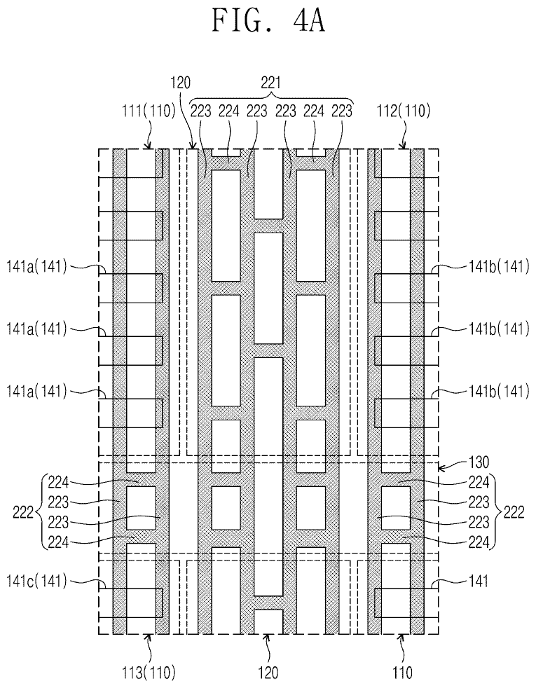

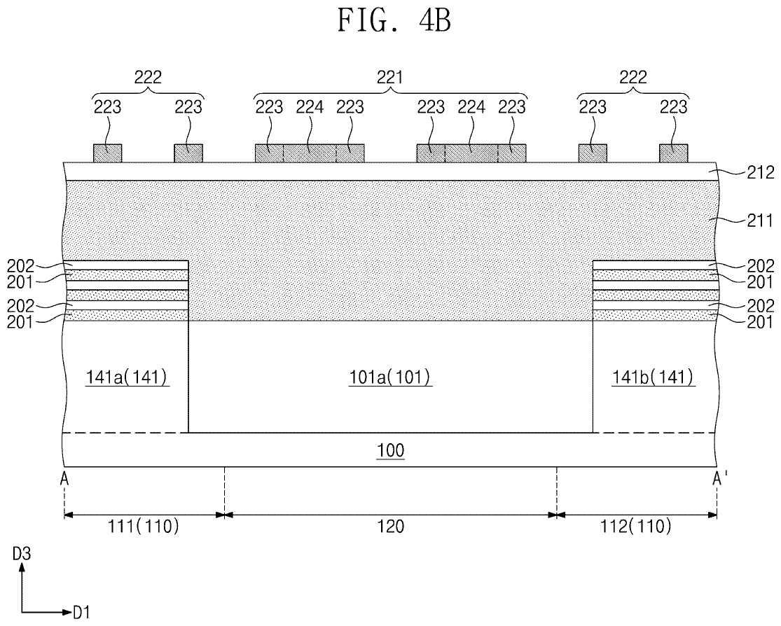

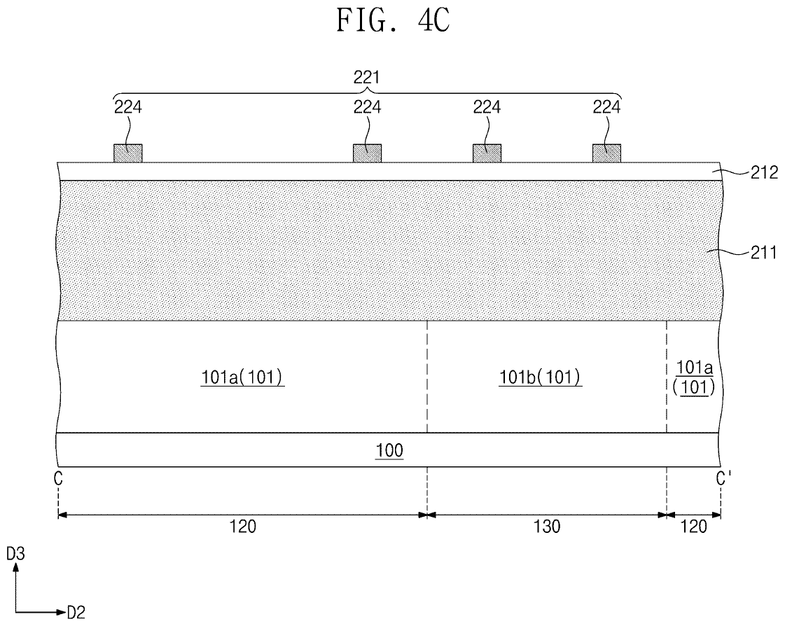

Referring to FIGS. 4A, 4B, and 4C, the photoresist layer 213 may be patterned to form first photoresist patterns 221 and second photoresist patterns 222. Each of the first and second photoresist patterns 221 and 222 may include photo line parts 223 and photo connection parts 224. The photo line part 223 may extend in a second direction D2. The photo line parts 223 may be spaced apart from each other in a first direction D1. The photo connection part 224 may extend in the first direction D1. The photo connection part 224 may connect the photo line parts 223 to each other.

The first photoresist pattern 221 may overlap in a third direction D3 with a first interface region 120 and a second interface region 130. The second photoresist pattern 222 may overlap in the third direction D3 with a block region 110 and the second interface region 130. The first photoresist pattern 221 may be disposed between the second photoresist patterns 222.

The first and second photoresist patterns 221 and 222 may be formed by a negative tone development (NTD). In this case, the patterning process of the photoresist layer 213 may include using a photomask to expose the photoresist layer 213, and removing unexposed portions of the photoresist layer 213. In some embodiments, the first and second photoresist patterns 221 and 222 may be formed by a positive tone development (PTD).

In some embodiments, the patterning process of the photoresist layer 213 may include measuring a distance between the block regions 110 spaced apart from each other in the first direction D1, calculating the number of photo line parts 223 which will be disposed between the block regions 110 on the basis of the measured distance, and manufacturing a photomask on the basis of the calculated number, and using the manufactured mask to pattern the photoresist layer 213.

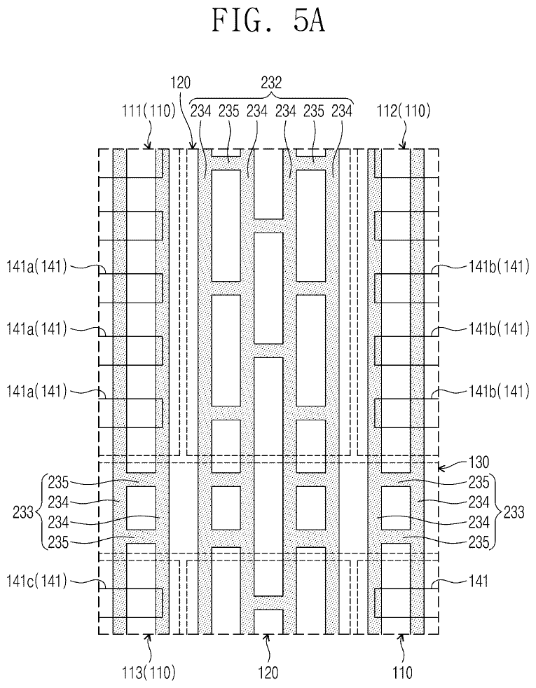

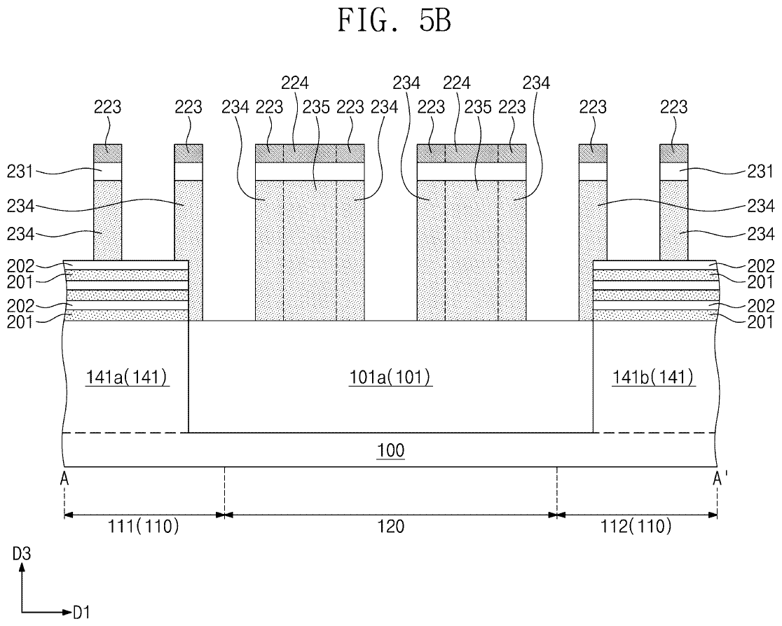

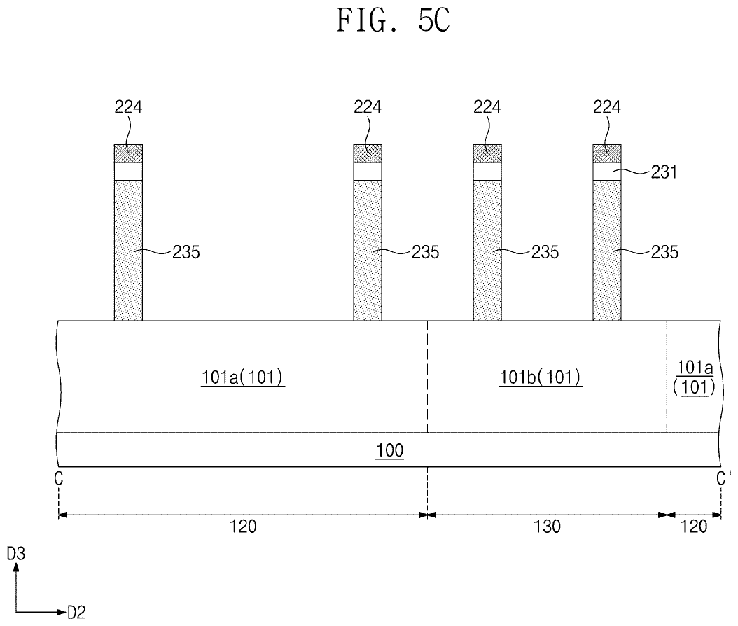

Referring to FIGS. 5A, 5B, and 5C, the first and second photoresist patterns 221 and 222 may be used as an etching mask to pattern the mask layer 212 and the preliminary pattern layer 211.

The mask layer 212 may be patterned to form mask patterns 231. The preliminary pattern layer 211 may be patterned to form first sacrificial patterns 232 and second sacrificial patterns 233.

The first photoresist pattern 221 may be transferred to form the first sacrificial pattern 232. The second photoresist pattern 222 may be transferred to form the second sacrificial pattern 233. The first sacrificial pattern 232 may be disposed between the second sacrificial patterns 233. The first sacrificial pattern 232 may overlap in the third direction D3 with the first interface region 120 and the second interface region 130. The second sacrificial pattern 233 may overlap in the third direction D3 with the block region 110 and the second interface region 130.

Each of the first and second sacrificial patterns 232 and 233 may include sacrificial line parts 234 and sacrificial connection parts 235. The sacrificial line part 234 may extend in the second direction D2. The sacrificial line parts 234 may be spaced apart from each other in the first direction D1. The sacrificial connection part 235 may extend in the first direction D1. The sacrificial connection part 235 may connect the sacrificial line parts 234 to each other.

After the formation of the first and second sacrificial patterns 232 and 233, the first and second photoresist patterns 221 and 222 may be removed. In some embodiments, after the formation of the mask patterns 231 and before the patterning of the preliminary pattern layer 211, the first and second photoresist patterns 221 and 222 may be removed.

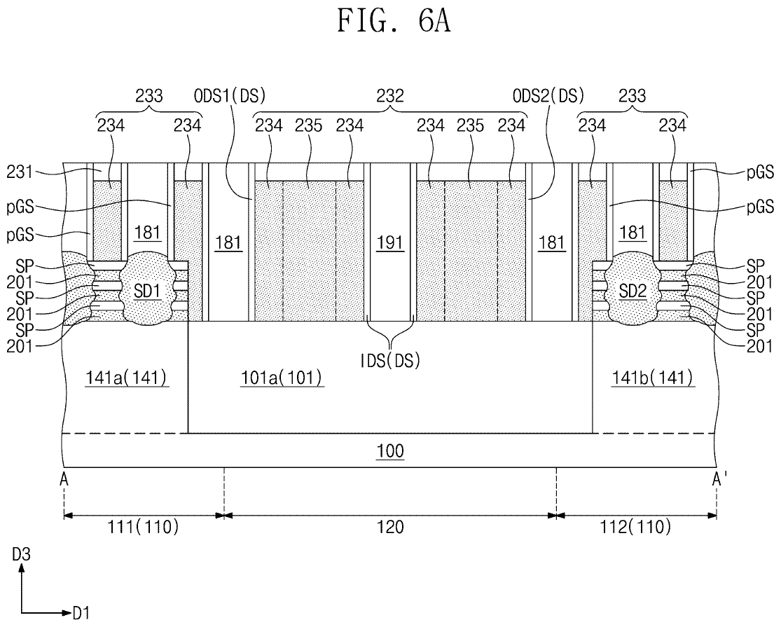

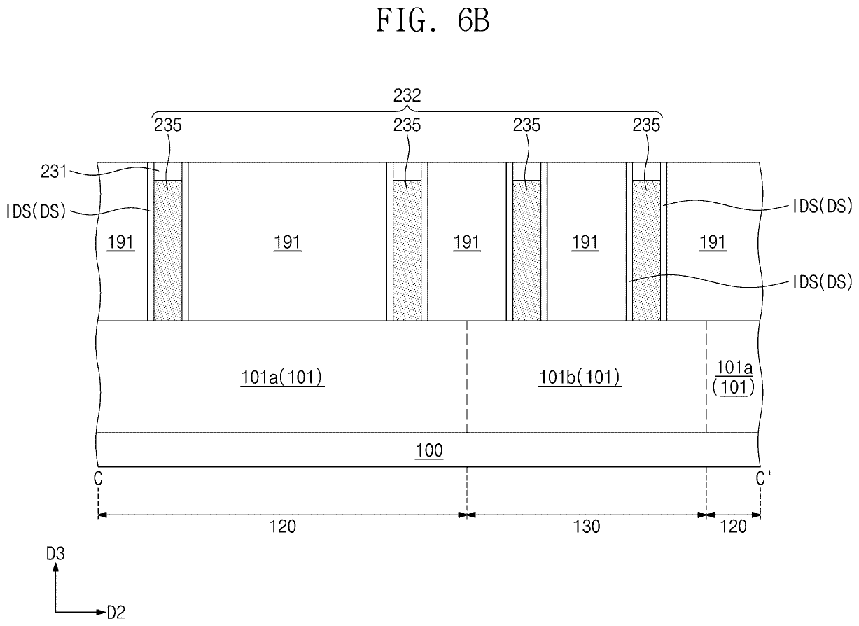

Referring to FIGS. 6A and 6B, preliminary gate spacers pGS and dummy spacers DS may be formed. The preliminary gate spacer pGS may be formed on a sidewall of the second sacrificial pattern 233. The dummy spacer DS may be formed on a sidewall of the first sacrificial pattern 232. The preliminary gate spacer pGS may include a dielectric material.

The dummy spacers DS may include outer dummy spacers ODS1 and ODS2 and inner dummy spacers IDS. The first sacrificial pattern 232 may be provided between the outer dummy spacers ODS1 and ODS2. The inner dummy spacers IDS may be surrounded by the first sacrificial pattern 232.

The mask patterns 231, the preliminary gate spacers pGS, and the dummy spacers DS may be used as an etching mask to etch the semiconductor layer 202 and the sacrificial layers 201. The semiconductor layer 202 may be etched to form semiconductor patterns SP. The semiconductor layer 202 may be divided into the semiconductor patterns SP.

Source/drain patterns SD1 and SD2 may be formed. The source/drain patterns SD1 and SD2 may be formed by an epitaxial growth process in which the semiconductor patterns SP and the etched sacrificial layers 201 are used as seeds.

There may be formed a first interlayer dielectric layer 181, first inner dielectric layers 191, and second inner dielectric layers (see 192 of FIG. 1I). The first interlayer dielectric layer 181, the first inner dielectric layers 191, and the second inner dielectric layers 192 may be formed simultaneously with each other. The first interlayer dielectric layer 181, the first inner dielectric layers 191, and the second inner dielectric layers 192 may be formed in the same process.

The first inner dielectric layer 191 may be surrounded by the first sacrificial pattern 232. The second inner dielectric layer 192 may be surrounded by the second sacrificial pattern 233.

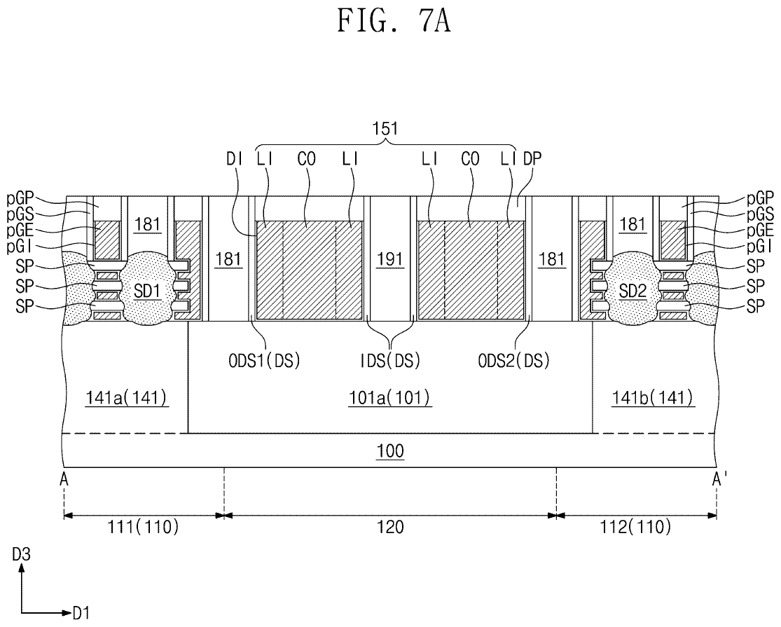

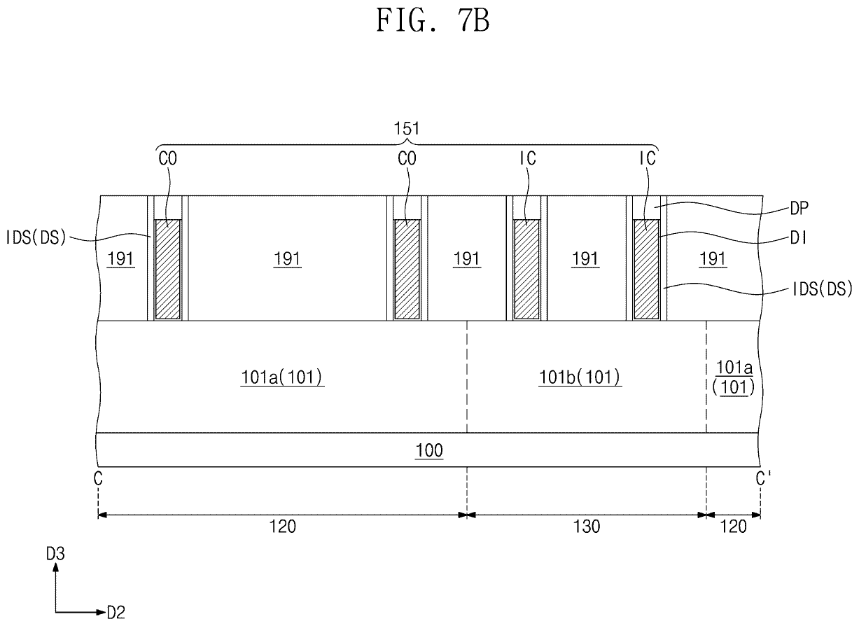

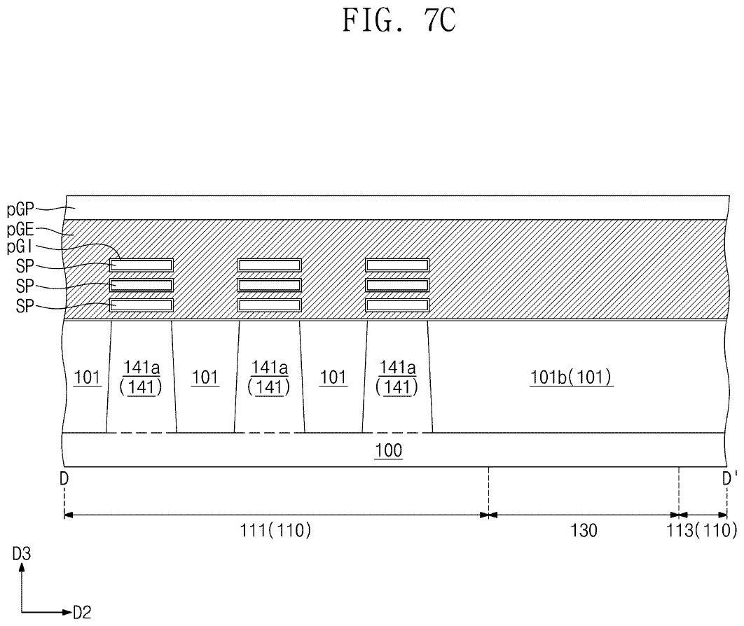

Referring to FIGS. 7A, 7B, and 7C, the sacrificial layers 201, the mask patterns 231, and the first and second sacrificial patterns 232 and 233 may be removed. A preliminary gate electrode pGE and a preliminary gate capping pattern pGP may be formed in an empty space from which the sacrificial layer 201 and the second sacrificial pattern 233 are removed.

A dummy dielectric layer D1, a dummy structure 151 or 152, and a dummy capping pattern DP may be formed in an empty space from which the first sacrificial pattern 232 is removed. A line part LI of the dummy structure 151 or 152 may be formed in an empty space from which a sacrificial line part 234 of the first sacrificial pattern 232 is removed. A connection part CO or an interface connection part IC of the dummy structure 151 or 152 may be formed in an empty space from which a sacrificial connection part 235 of the first sacrificial pattern 232 is removed.

Referring to FIGS. 1A, 1B, 1C, 1d, 1E, 1F, 1G, 1H, and 1I, gate separation layers 170 may be formed. The gate separation layer 170 may separate a preliminary gate dielectric layer pGI into a gate dielectric layer GI and an interface dielectric layer II. The gate separation layer 170 may separate the preliminary gate electrode pGE into a gate electrode GE and an interface pattern 160. The gate separation layer 170 may separate the preliminary gate capping pattern pGP into a gate capping pattern GP and an interface capping pattern IP. The gate separation layer 170 may separate the preliminary gate spacer pGS into a gate spacer GS and an interface spacer IS.

A second interlayer dielectric layer 182 may be formed. Active contacts AC and gate contacts GC may be formed.

In a method of fabricating a semiconductor device according to some embodiments, the sacrificial connection parts 235 of the sacrificial patterns 232 and 233 may be disposed on the interface regions 120 and 130 where the fin patterns 141 are not disposed, and thus it may be possible to prevent or improve leaning issues of the sacrificial patterns 232 and 233. Accordingly, improved stability may be achieved in the fabrication of the semiconductor device.

In a method of fabricating a semiconductor device according to some embodiments, the photo connection parts 224 of the photoresist pattern 221 or 222 may be obliquely arranged to relatively reduce an interval in the second direction D2 of the photo connection parts 224 connected to the photo line part 223. it may thus be possible to prevent or improve shrinkage in the first direction D1 of the photo line parts 223 of the photoresist pattern 221 or 222. For example, when the photoresist pattern 221 or 222 is formed by a negative tone development, shrinkage of the photo line parts 223 may be prevented or improved. Accordingly, improved stability may be achieved in the fabrication of the semiconductor device.

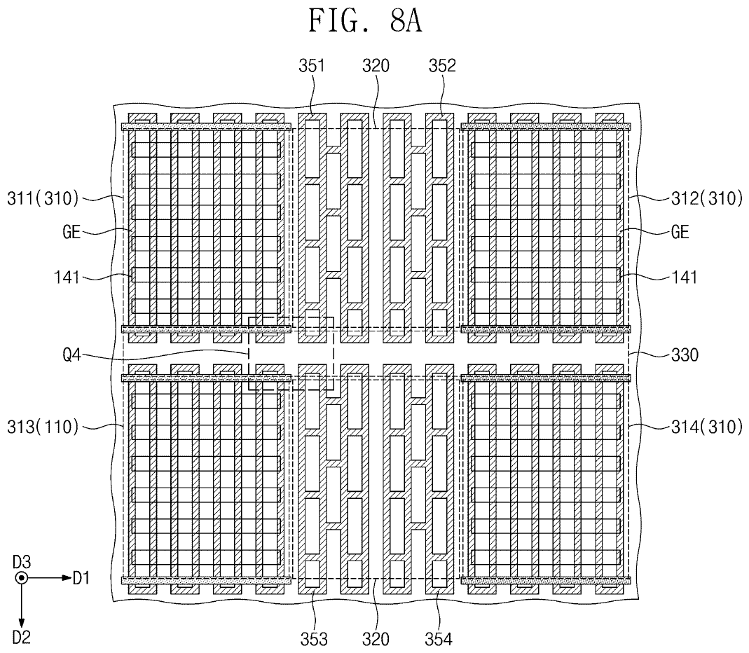

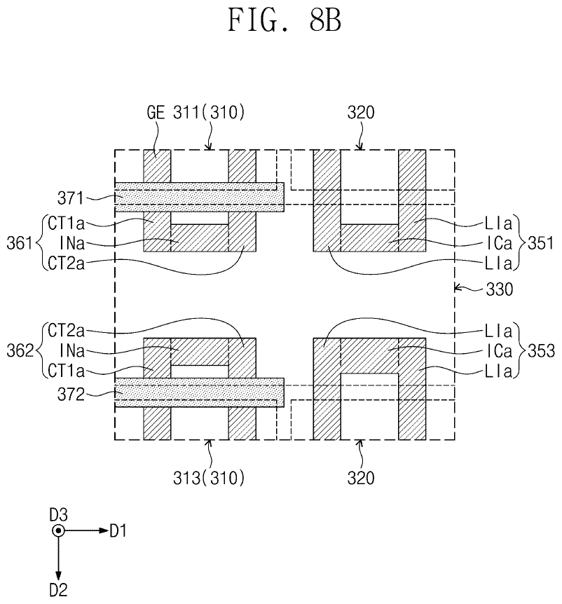

FIG. 8A illustrates a plan view showing a semiconductor device according to some embodiments. FIG. 8B illustrates an enlarged view showing section Q4 of FIG. 8A. A semiconductor device of FIGS. 8A and 8B may be similar to the semiconductor device of FIGS. 1A to 1I, except for that discussed below.

Referring to FIG. 8A, block regions 310 may include a first block region 311 and a second block region 312 that are adjacent to each other in the first direction D1, and may also include a third block region 313 and a fourth block region 314 that are adjacent to each other in the first direction D1. The third block region 313 may be adjacent in the second direction D2 to the first block region 311. The fourth block region 314 may be adjacent in the second direction D2 to the second block region 312.

A first dummy structure 351 and a second dummy structure 352 may be disposed between the first block region 311 and the second bloc region 312. The first dummy structure 351 and the second dummy structure 352 may be spaced apart from each other in the first direction D1. A third dummy structure 353 and a fourth dummy structure 354 may be disposed between the third block region 313 and the fourth bloc region 314. The third dummy structure 353 and the fourth dummy structure 354 may be spaced apart from each other in the first direction D1.

The first and third dummy structures 351 and 353 may be spaced apart from each other in the second direction D2. The first and third dummy structures 351 and 353 may be disposed on an imaginary straight line that extends in the second direction D2. The second and fourth dummy structures 352 and 354 may be spaced apart from each other in the second direction D2. The second and fourth dummy structures 352 and 354 may be disposed on an imaginary straight line that extends in the second direction D2.

A first interface region 320 may include the first and second dummy structures 351 and 352 or the third and fourth dummy structures 353 and 354. The first and third dummy structures 351 and 353 may be spaced apart from each other on a second interface region 330. The second and fourth dummy structures 352 and 354 may be spaced apart from each other on the second interface region 330.

Referring to FIG. 8B, an interface connection part ICa of the first dummy structure 351 may be connected to ends of line parts LIa of the first dummy structure 351. An interface connection part ICa of the third dummy structure 353 may be connected to ends of line parts LIa of the third dummy structure 353. The line part LIa of the first dummy structure 351 and the line part LIa of the third dummy structure 353 may be spaced apart from each other in the second direction D2.

A first gate separation layer 371 and a second gate separation layer 372 may be provided between the first block region 311 and the third block region 313. A first interface pattern 361 may be provided to contact the first gate separation layer 371, and a second interface pattern 362 may be provided to contact the second gate separation layer 372. The first interface pattern 361 and the second interface pattern 362 may be provided between the first gate separation layer 371 and the second gate separation layer 372.

Each of the first and second interface patterns 361 and 362 may include a first contact part CT1a, a second contact part CT2a, and an intervening part INa. The first contact part CT1a and the second contact part CT2a of the first interface pattern 361 may be in contact with the first gate separation layer 371 and spaced apart from the second gate separation layer 372. The first contact part CT1a and the second contact part CT2a of the second interface pattern 362 may be in contact with the second gate separation layer 372 and spaced apart from the first gate separation layer 371.

The first interface pattern 361 may be spaced apart in the second direction D2 from the second interface pattern 362. The first contact part CT1a of the first interface pattern 361 and the first contact part CT1a of the second interface pattern 362 may be spaced apart from each other in the second direction D2. The first contact part CT1a of the first interface pattern 361 and the first contact part CT1a of the second interface pattern 362 may be disposed on an imaginary straight line that extends in the second direction D2.

The second contact part CT2a of the first interface pattern 361 and the second contact part CT2a of the second interface pattern 362 may be spaced apart from each other in the second direction D2. The second contact part CT2a of the first interface pattern 361 and the second contact part CT2a of the second interface pattern 362 may be disposed on an imaginary straight line that extends in the second direction D2.

The intervening part INa of the first interface pattern 361 and the intervening part INa of the second interface pattern 362 may be spaced apart from each other in the second direction D2.

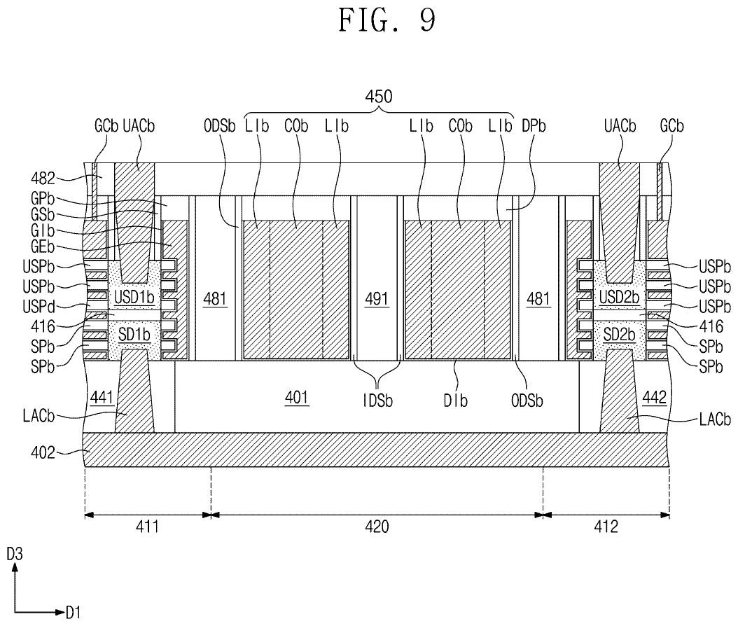

FIG. 9 illustrates a cross-sectional view showing a semiconductor device according to some embodiments. A semiconductor device of FIG. 9 may be similar to the semiconductor device of FIGS. 1A to 1I, except for that discussed below

Referring to FIG. 9, a semiconductor device may include first fin patterns 441 and second fin patterns 442. The first fin pattern 441 and the second fin pattern 442 may be spaced apart from each other in the first direction D1. The first fin pattern 441 may be disposed on a first block region 411. The second fin pattern 442 may be disposed on a second block region 412. An interface region 420 may be disposed between the first and second block regions 411 and 412.

A device isolation layer 401 may be provided to surround the first and second fin patterns 441 and 442.

Semiconductor patterns SPb and an upper semiconductor patterns USPb may be provided to overlap in the third direction D3 with the first and second fin patterns 441 and 442. The upper semiconductor pattern USPb may be located at a higher level than that of the semiconductor patterns SPb.

Intervening dielectric patterns 416 may be provided. The intervening dielectric pattern 416 may be disposed between the semiconductor pattern SPb and the upper semiconductor pattern USPb. The intervening dielectric pattern 416 may include a dielectric material.

A first source/drain pattern SD1b may be provided on the first fin pattern 441. A second source/drain pattern SD2b may be provided on the second fin pattern 442.

A first upper source/drain pattern USD1b may be provided which overlaps in the third direction D3 with the first source/drain pattern SD1b, and a second upper source/drain pattern USD2b may be provided which overlaps in the third direction D3 with the second source/drain pattern SD2b. The first and second upper source/drain patterns USD1b and USD2b may be epitaxial patterns formed by a selective epitaxial growth (SEG) process. The first and second upper source/drain patterns USD1b and USD2b may be in contact with the upper semiconductor patterns USPb.

Gate electrodes GEb may be provided. The gate electrode GEb may surround the semiconductor patterns SPb and the upper semiconductor patterns USPb.

Gate dielectric layers GIb may be provided. The gate dielectric layer GIb may separate the gate electrode GEb from the semiconductor patterns SPb and the upper semiconductor patterns USPb. Gate spacers GSb may be provided on opposite sides of the gate electrode GEb. A gate capping pattern GPb may be provided on the gate electrode GEb.

A dummy structure 450 may be provided. The dummy structure 450 may include line parts LIb and connection parts COb that connect the line parts LIb to each other. Outer dummy spacers ODSb may be provided which are spaced apart from each other across the dummy structure 450. Inner dummy spacers IDSb may be provided which are surrounded by the dummy structure 450.

A dummy dielectric layer DIb may be provided to contact the dummy structure 450. A dummy capping pattern DPb may be provided on the dummy structure 450.

A first interlayer dielectric layer 481 and a second interlayer dielectric layer 482 may be provided. A gate contact GCb may be provided to contact the gate electrode GEb. An upper active contact UACb may be provided to contact the upper source/drain pattern USD1b or USD2b. A lower active contact LACb may be provided to contact the source/drain pattern SD1b or SD2b. The lower active contact LACb may penetrate the fin pattern 441 or 442.

A lower conductive line 402 may be provided. The lower conductive line 402 may be electrically connected to the lower active contact LACb. In some embodiments, the lower conductive line 402 may be a power line.

A semiconductor device according to some embodiments of inventive concepts may include a dummy structure to reduce a size of the semiconductor device.

A semiconductor device according to some embodiments of inventive concepts may improve in stability of fabrication process.

Although some embodiments of inventive concepts have been discussed with reference to accompanying figures, it will be understood that various changes in form and details may be made therein without departing from the spirit and scope of invention. It therefore will be understood that the embodiments described above are just illustrative but not limitative in all aspects.

What is claimed is:

1. A semiconductor device, comprising:
a first fin pattern;
a first source/drain pattern on the first fin pattern;
a second fin pattern spaced apart in a first direction from the first fin pattern;
a second source/drain pattern on the second fin pattern;
a first gate electrode overlapping the first fin pattern and extending in a second direction, the second direction crossing the first direction;
a second gate electrode overlapping the second fin pattern and extending in the second direction; and
a first dummy structure between the first fin pattern and the second fin pattern and between the first gate electrode and the second gate electrode,
wherein the first dummy structure comprises a first line part extending in the second direction, a second line part extending in the second direction, a third line part extending in the second direction, a first connection part and a second connection part connecting the first line part and the second line part to each other, and a third connection part connecting the second line part and third line part to each other,
wherein the first connection part, the second connection part, and the third connection part are spaced apart from each other in the second direction, and
wherein a distance in the second direction between the first connection part and the second connection part is greater than a distance in the second direction between the first connection part and the third connection part, and
wherein the distance in the second direction between the first connection part and the second connection part is greater than a distance in the second direction between the second connection part and the third connection part.

2. The semiconductor device of claim 1,
wherein the first dummy structure further comprises a fourth line part extending in the second direction,
wherein the first dummy structure further comprises a fourth connection part connecting the third line part and the fourth line part to each other, and
wherein the distance in the second direction between the first connection part and the third connection part is the same as a distance in the second direction between the fourth connection part and the third connection part.

3. The semiconductor device of claim 1, further comprising:
an inner dummy spacer surrounded by the first line part, the second line part, the first connection part, and the second connection part.

4. The semiconductor device of claim 3, further comprising:
an inner dielectric layer surrounded by the inner dummy spacer.

5. The semiconductor device of claim 1, further comprising:
a third fin pattern spaced apart in the second direction from the first fin pattern; and
a first gate separation layer and a second gate separation layer between the first fin pattern and the third fin pattern,
wherein a distance in the second direction between the first connection part and the first gate separation layer is less than a distance in the second direction between the third connection part and the first gate separation layer.

6. The semiconductor device of claim 1, wherein
the first dummy structure further comprises an interface connection part,
wherein the interface connection part connects the first line part and the second line part to each other.

7. The semiconductor device of claim 1, wherein
the first dummy structure further comprises an interface connection part that connects the first line part and the second line pars to each other,
the first connection part is between the second connection part and the interface connection part, and
the distance in the second direction between the first connection part and the second connection part is greater than a distance in the second direction between the first connection part and the interface connection part.

8. The semiconductor device of claim 1, further comprising:
a second dummy structure between the first dummy structure and the second gate electrode,
wherein the second dummy structure comprises a fourth line part extending in the second direction, a fifth line part extending in the second direction, a sixth line part extending in the second direction, a fourth connection part and a fifth connection part connecting the fourth line part and the fifth line part to each other, and a sixth connection part connecting the fifth line part and the sixth line part to each other,
wherein the fourth connection part, the fifth connection part, and the sixth connection part are spaced apart from each other in the second direction, and
wherein a distance in the second direction between the fourth connection part and the fifth connection part is greater than a distance in the second direction between the fourth connection part and the sixth connection part.

9. A semiconductor device, comprising:
a first fin pattern;
a first source/drain pattern on the first fin pattern;
a second fin pattern spaced apart in a first direction from the first fin pattern;
a second source/drain pattern on the second fin pattern;
a first gate electrode overlapping the first fin pattern and extending in a second direction, the second direction crossing the first direction;
a second gate electrode overlapping the second fin pattern and extending in the second direction; and
a first dummy structure between the first fin pattern and the second fin pattern and between the first gate electrode and the second gate electrode,
wherein the first dummy structure comprises a first line part extending in the second direction, a second line part extending in the second direction, a third line part extending in the second direction, a first connection part and a second connection part connecting the first line part and the second line part to each other, and a third connection part connecting the second line part and the third line part to each other,
wherein the first connection part, the second connection part, and the third connection part are spaced apart from each other in the second direction, and
wherein the third connection part is between the first connection part and the second connection part.

10. The semiconductor device of claim 9, further comprising:
a third fin pattern spaced apart in the second direction from the first fin pattern;
a third source/drain pattern on the third fin pattern;
a third gate electrode overlapping the third fin pattern and extending in the second direction;
a first gate separation layer and a second gate separation layer between the first gate electrode and the third gate electrode; and
a first interface pattern between the first gate separation layer and the second gate separation layer,
wherein the first and second gate separation layers are adjacent to each other, and
wherein the first interface pattern comprises a first contact part in contact with the first gate separation layer, a second contact part in contact with the first gate separation layer, and a first intervening part connecting the first contact part and the second contact part to each other, and
wherein the first intervening part is spaced apart from the first gate separation layer.

11. The semiconductor device of claim 10, wherein the first contact part and the second contact part are in contact with the second gate separation layer.

12. The semiconductor device of claim 11,
an inner interface spacer, wherein
the first interface pattern further comprises a second intervening part,
the second intervening part connects the first contact part and the second contact parts to each other and is spaced apart from the second gate separation layer, and
the inner interface spacer surrounded by the first contact part, the second contact part, the first intervening part, and the second intervening part.

13. The semiconductor device of claim 10, further comprising:
a second interface pattern between the first gate separation layer and the second gate separation layer,
wherein the first interface pattern and the second interface pattern are spaced apart from each other,
wherein the second interface pattern comprises a third contact part in contact with the second gate separation layer, a fourth contact part in contact with the second gate separation layer, and a second intervening part connecting the third contact part and the fourth contact part to each other, and
wherein the second intervening part is spaced apart from the second gate separation layer.

14. The semiconductor device of claim 10,
wherein the first dummy structure further comprises a first interface connection part that connects the first line part and the second line part to each other,
wherein the first interface connection part is between the first gate separation layer and the second gate separation layer.

15. The semiconductor device of claim 14,
wherein a sidewall of the first interface connection part and a sidewall of the first intervening part are parallel to the first direction,
wherein the sidewall of the first interface connection part and the sidewall of the first intervening part are on an imaginary straight line extending in the first direction.

16. The semiconductor device of claim 14,
wherein the first dummy structure further comprises a second interface connection part that connects the first line part and the second line part to each other, and
wherein the second interface connection part is between the first gate separation layer and the second gate separation layer.

17. The semiconductor device of claim 14, further comprising:
a second dummy structure spaced apart in the second direction from the first dummy structure,
wherein the second dummy structure comprises a fourth line part extending in the second direction, a fifth line part extending in the second direction, a sixth line part extending in the second direction, a fourth connection part, a fifth connection part, a second interface connection part, and a sixth connection part,
wherein the fourth connection part, the fifth connection part, and the second interface connection part connect the fourth line part and the fifth line part to each other, and
wherein the sixth connection part connects the fifth line part and the sixth line part to each other,
wherein the fourth connection part, the fifth connection part, the sixth connection part, and the second interface connection part are spaced apart from each other in the second direction,
wherein the sixth connection part is between the fourth connection part and the fifth connection part, and
wherein the second interface connection part is between the first gate separation layer and the second gate separation layer and between the first connection part and the fourth connection part.

18. A semiconductor device, comprising:
a first fin pattern;
a first source/drain pattern on the first fin pattern;
a second fin pattern spaced apart in a first direction from the first fin pattern;
a second source/drain pattern on the second fin pattern;
a first gate electrode overlapping the first fin pattern and extending in a second direction, the second direction crossing the first direction;
a second gate electrode overlapping the second fin pattern and extending in the second direction;
a dummy structure between the first fin pattern and the second fin pattern; and
a plurality of inner dummy spacers surrounded by the dummy structure,
wherein the dummy structure comprises a first line part extending in the second direction, a second line part extending in the second direction, a third line part extending in the second direction, a first connection part, a second connection part, a third connection part, a fourth connection part, and a fifth connection part,
wherein the first connection part, the second connection part, and the third connection part connect the first line part and the second line part to each other,
where the fourth connection part and the fifth connection part connect the second line part and the third line part to each other,
wherein the fourth connection part is between the first connection part and the second connection part,
wherein the fifth connection part is between the second connection part and the third connection part,
wherein the inner dummy spacers comprise a first inner dummy spacer, a second inner dummy spacer, and a third inner dummy spacer,
the first inner dummy spacer is surrounded by the first line part, the second line part, the first connection part, and the second connection part,
the second inner dummy spacer is surrounded by the first line part, the second line part, the second connection part, and the third connection part, and
the third inner dummy spacer is surrounded by the second line part, the third line part, the fourth connection part, and the fifth connection part.

19. The semiconductor device of claim 18, further comprising:
a first outer dummy spacer and a second outer dummy spacer that are spaced apart in the first direction from each other across the dummy structure,
wherein the first inner dummy spacer, the second inner dummy spacer, and the third inner dummy spacer are between the first outer dummy spacer and the second outer dummy spacer.

20. The semiconductor device of claim 18, wherein
the first connection part, the second connection part, and the third connection part are connected to a first sidewall of the second line part,
the fourth connection part and the fifth connection part are connected to a second sidewall of the second line part, and
the second sidewall of the second line part is opposite the first sidewall of the second line part.
